(19) United States
(12) Patent Application Publication
(10) Pub. No.: US 2023/0080617 A1
(43) Pub. Date: Mar. 16, 2023

(54) SENSOR DEVICE

(71) Applicant: HITACHI ASTEMO, LTD., Hitachinaka-shi, Ibaraki (JP)

(72) Inventors: Masahiro MATSUMOTO, Chiyoda-ku, Tokyo (JP); Akira KOTABE, Hitachinaka-shi, Ibaraki (JP); Akeo SATOH, Hitachinaka-shi, Ibaraki (JP)

(73) Assignee: HITACHI ASTEMO, LTD., Hitachinaka-shi, Ibaraki (JP)

(21) Appl. No.: 17/800,869

(22) PCT Filed: Dec. 28, 2020
(86) PCT No.: PCT/JP2020/049086

§ 371 Date: Aug. 18, 2022

(30) Foreign Application Priority Data
Mar. 13, 2020 (JP) 2020-043655

(51) Int. Cl. G06F 3/06; G01F 15/061

(52) U.S. Cl. CPC G06F 3/062; G01F 15/061; G06F 3/0629; G06F 3/0679

(57) ABSTRACT

There is a possibility that unauthorized writing of adjustment information occurs in a sensor device in which the adjustment information of the sensor device can be written from outside. A sensor device 1 of the present embodiment includes a detection unit 2 configured to detect a physical quantity, a nonvolatile memory 5 configured to store adjustment information 6 and protection information 7, an adjustment unit 3 configured to adjust an output signal of the detection unit 2 based on contents of the adjustment information 6, an output unit 4 configured to output an output of the adjustment unit 3 to an outside via an external terminal 12, a communication unit 11 configured to communicate with the outside of the sensor device 1 via an external terminal 13, a writing unit 8 configured to perform writing process to the nonvolatile memory 6 based on information from the communication unit 11, an erasing unit 9 configured to perform erasing process of the nonvolatile memory 5 based on information from the communication unit 11, and a reading unit 10 configured to perform reading process from the nonvolatile memory 5 based on information from the communication unit 11.

### TECHNICAL FIELD

The present invention relates to a sensor device capable of adjusting a sensor characteristic based on adjustment information stored in a nonvolatile memory, and more particularly to a sensor device capable of preventing unauthorized writing of adjustment information stored in a nonvolatile memory.

### BACKGROUND ART

As an example of a sensor device capable of preventing erroneous writing and erroneous erasing of adjustment information stored in a nonvolatile memory, there is a technology described in PTL 1. In PTL 1, erroneous writing and unauthorized writing to the nonvolatile memory are prevented by fusing the fuse ROM to physically fix a write signal to the nonvolatile memory to an OFF state.

In addition, as an example of an integrated circuit device capable of preventing erroneous writing of information stored in a nonvolatile memory, there is a technology described in PTL 2. In PTL 2, erroneous writing and unauthorized reading to the nonvolatile memory are prevented by protecting writing or reading of the nonvolatile memory based on the protection information stored in the nonvolatile memory.

### CITATION LIST

### Patent Literature

PTL 1: JP 2003-240652 A

PTL 2: JP 2008-262294 A

### SUMMARY OF INVENTION

### Technical Problem

In PTL 1, erroneous writing and unauthorized writing to the nonvolatile memory are prevented by fusing the fuse ROM to physically fix a write signal to the nonvolatile memory to an OFF state. Since the fuse ROM is used in PTL 1, there are problems that a special process for configuring the fuse ROM is required, a dedicated pad for fusing the fuse ROM is required to be separately provided, and when a transistor is used for fusing the fuse ROM, the size of the transistor increases. In addition, there is also a problem in ensuring the reliability of the fusing portion of the fuse ROM. For these reasons, it is difficult to mount a fuse ROM and a nonvolatile memory (particularly, a flash memory) on the same chip, and if the fuse ROM and the nonvolatile memory are mounted on the same chip, problems such as an increase in process cost, an increase in chip size, and a decrease in reliability occur. Therefore, when the fuse ROM is used, problems such as miniaturization, cost reduction, and reliability of the sensor device arise.

In addition, in PTL 2, erroneous writing to the nonvolatile memory is prevented by protecting writing or reading of the nonvolatile memory based on the protection information stored in the nonvolatile memory. Since the present patent is to prevent unauthorized reading and erroneous writing of a program stored in an integrated circuit device, reading and writing of a nonvolatile memory are protected, but erasure of the nonvolatile memory is basically not protected since reuse of the nonvolatile memory is considered. Therefore, when the present technology is used for a sensor device, there are problems that adjustment information stored in the nonvolatile memory cannot be verified, and the information stored in the nonvolatile memory may be unauthorizedly erased. In the present technology, since the information stored in the nonvolatile memory can be erased, the adjustment information stored in the sensor device can be unauthorizedly rewritten. As a result, malfunction of the sensor device may cause malfunction of the entire system which uses the sensor device and cause serious damage. For these reasons, it is necessary to prevent the adjustment information of the sensor device from being rewritten by an unauthorized operation from the outside of the sensor device. In particular, measures against unauthorized rewriting of the adjustment information stored in the sensor device are essential due to the problem of information security.

The present invention has been made in view of the above circumstances, and an object thereof is to provide a sensor device capable of preventing unauthorized writing of adjustment information of the sensor device written in a nonvolatile memory.

### Solution to Problem

In order to solve the above problems, a sensor device of the present invention includes: a detection unit configured to detect a physical quantity; a nonvolatile memory configured to store adjustment information; an adjustment unit configured to adjust an output signal of the detection unit based on the adjustment information; an output unit configured to output an output of the adjustment unit to an outside; a communication unit configured to communicate with the outside; a writing unit configured to perform writing to the nonvolatile memory based on information from the communication unit; a reading unit configured to perform reading from the nonvolatile memory based on information from the communication unit; and an erasing unit configured to perform erasing of the nonvolatile memory based on information from the communication unit, wherein an area that stores protection information is arranged in the nonvolatile memory, and operations of the writing unit and the erasing unit are prohibited based on the protection information.

### Advantageous Effects of Invention

According to the present invention, it is possible to provide a sensor device capable of preventing unauthorized writing of adjustment information of the sensor device written in a nonvolatile memory.

### BRIEF DESCRIPTION OF DRAWINGS

FIG. 1 is a configuration diagram of a sensor device according to a first embodiment.

FIG. 2 is a memory map of a nonvolatile memory 5.

FIG. 3 illustrates a configuration of a communication command.

FIG. 4 illustrates processing contents for a communication command instructing writing to the nonvolatile memory 5.

FIG. 5 illustrates processing contents for a communication command for instructing erasing of the nonvolatile memory 5.

FIG. 6 illustrates processing contents for a communication command for instructing reading from the nonvolatile memory 5.

FIG. 7 illustrates a flow of writing adjustment information 6 and protection information 7 into the nonvolatile memory 5.

FIG. 8 is a configuration diagram of a sensor device according to a second embodiment.

FIG. 9 illustrates a configuration of a communication command for erasing the protection information 7.

[FIG. 10 illustrates processing contents of a communication command for erasing the protection information 7.

### DESCRIPTION OF EMBODIMENTS

Hereinafter, embodiments of the present invention will be described with reference to the drawings. Note that the embodiments can be combined as long as there is no contradiction.

### First Embodiment

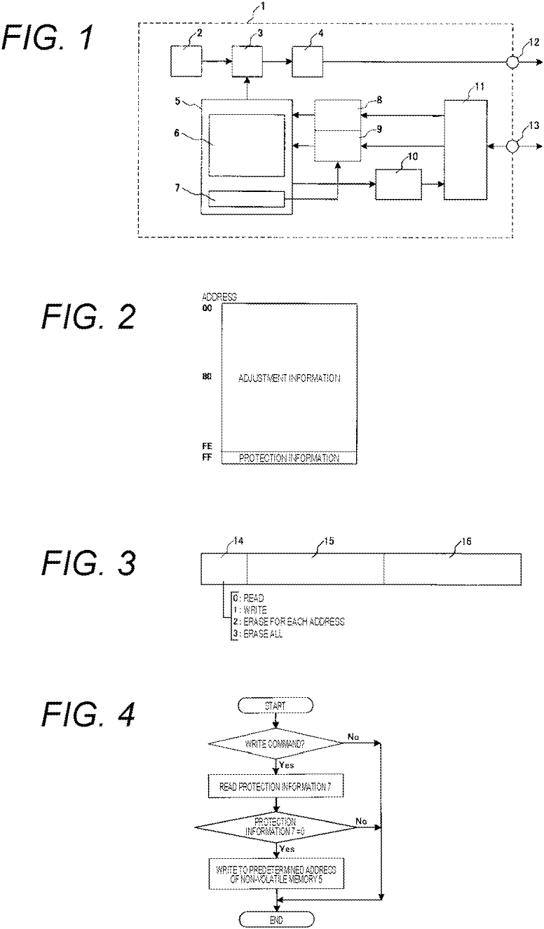

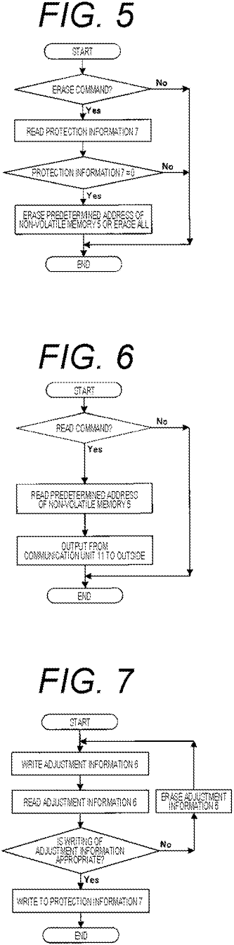

First, a sensor device according to the first embodiment of the present invention will be described with reference to FIG. 1 to FIG. 7. FIG. 1 is a configuration diagram of the sensor device according to the first embodiment, FIG. 2 is a memory map of a nonvolatile memory 5, FIG. 3 is a configuration of a communication command, FIG. 4 illustrates processing contents for a communication command instructing writing to the nonvolatile memory 5, FIG. 5 illustrates processing contents for a communication command for instructing erasing of the nonvolatile memory 5, FIG. 6 illustrates processing contents for a communication command for instructing reading from the nonvolatile memory 5, and FIG. 7 illustrates a flow of writing adjustment information 6 and protection information 7 into the nonvolatile memory 5.

A sensor device 1 of the present embodiment includes a detection unit 2 configured to detect a physical quantity, a nonvolatile memory 5 configured to store adjustment information 6 and protection information 7, an adjustment unit 3 configured to adjust an output signal of the detection unit 2 based on contents of the adjustment information 6, an output unit 4 configured to output an output of the adjustment unit 3 to an outside via an external terminal 12, a communication unit 11 configured to communicate with the outside of the sensor device 1 via an external terminal 13, a writing unit 8 configured to perform writing process to the nonvolatile memory 5 based on information from the communication unit 11, an erasing unit 9 configured to perform erasing process of the nonvolatile memory 5 based on information from the communication unit 11, and a reading unit 10 configured to perform reading process from the nonvolatile memory 5 based on information from the communication unit 11.

Note that, an example of the detection unit 2 configured to detect a physical quantity includes a semiconductor element such as a flow rate measurement element molded by MEMS design. In addition, the adjustment unit 3, the output unit 4, the communication unit 11, the nonvolatile memory 5, the writing unit 8, the erasing unit 9, and the reading unit 10 are formed in the same integrated circuit (LSI). The semiconductor element and the integrated circuit may be formed by the same semiconductor element, or may be formed as different semiconductor elements.

The nonvolatile memory 5 includes a flash memory or an EEPROM. As illustrated in FIG. 2, the adjustment information 6 is arranged from an address 00 to an address FE, and the protection information 7 is arranged in an address FF. Furthermore, the communication device 11 processes a communication command as illustrated in FIG. 3. The communication command includes an operand part 14, an address part 15, and a data part 16, indicating operations (read, write, erase for each address, erase all, etc.) on the nonvolatile memory 5.

Next, processing contents of a communication command for instructing writing to the nonvolatile memory 5 in the present embodiment will be described with reference to FIG. 4. The communication command sent via the external terminal 13 is processed by the communication unit 11, and when it is determined as a write command, the writing unit 8 reads the protection information 7, and writes data to a predetermined address of the nonvolatile memory 5 when the protection information 7 is 0.

The initial value of the nonvolatile memory 5 is set to 0, so that writing and erasing to the nonvolatile memory 5 are not protected in the initial state. That is, when the protection information 7 is 0, writing process to the nonvolatile memory 5 is performed, and in other cases, the writing process is prohibited. In other words, the writing process is prohibited by the protection information 7.

Next, processing contents for a communication command for instructing erasure of the nonvolatile memory 5 in the present embodiment will be described with reference to FIG. 5. The communication command sent via the external terminal 13 is processed by the communication unit 11, and when it is determined as an erase command, the erasing unit 9 reads the protection information 7, and erases a predetermined address of the nonvolatile memory 5 or erases all when the protection information 7 is 0. That is, when the protection information 7 is 0, erasing process of the nonvolatile memory 5 is performed, and in other cases, the erasing process is prohibited. In other words, the erasing process is prohibited by the protection information 7.

Next, processing contents for a communication command for instructing reading from the nonvolatile memory 5 in the present embodiment will be described with reference to FIG. 6. The communication command sent via the external terminal 13 is processed by the communication unit 11, and when it is determined as a read command, the reading unit 10 reads data from a predetermined address of the nonvolatile memory 5, and the communication unit 11 outputs the data to the outside via the external terminal 13. That is, the reading process is always performed without being protected by the protection information 7.

Next, a writing procedure to the nonvolatile memory 5 in the present embodiment will be described with reference to FIG. 7. As shown in FIG. 7, writing to the nonvolatile memory 5 is performed by first writing to the adjustment information 6 arranged from the address 00 to the address FE of the nonvolatile memory 5, then reading the contents of the adjustment information 6 for verification, determining that writing to the adjustment information 6 is appropriate when the contents written to the adjustment information 6 matches the contents read from the adjustment information 6, completing writing of the protection information 7 if appropriate, and erasing the adjustment information 6 and redoing from the beginning if not appropriate. In this manner, the adjustment information 6 is first written, the verification of the adjustment information 6 is performed, and the protection information 7 is finally written, thereby prohibiting writing and erasing of the nonvolatile memory 5.

In this embodiment, after writing to the protection information 7 is performed, writing and erasing to the nonvolatile memory 5 can be completely prohibited. As a result, it is possible to prevent the adjustment information 6 of the sensor device 1 from being rewritten by an unauthorized operation from the external terminal 13, and as a result, it is possible to prevent malfunction of the entire system which uses the sensor device by preventing malfunction of the sensor device.

In this embodiment, even after writing to the protection information 7 is performed to protect the nonvolatile memory 5, the nonvolatile memory 5 can be read out. As a result, even if the contents of the nonvolatile memory 5 are rewritten by any chance, the contents of the nonvolatile memory 5 can be confirmed by sending a read command from the external terminal 13. In addition, it is possible to store a product identification code for ensuring traceability of the sensor device 1 in the adjustment information 6, and this product identification code can also be confirmed even after the protection of the nonvolatile memory 5 is performed, which can contribute to improvement in reliability of the sensor device 1.

Furthermore, since the protection information 7 for performing protection of the nonvolatile memory 5 is stored in the nonvolatile memory 5, the writing unit 8 for performing writing to the adjustment information 6, the erasing unit 9, and the reading unit 10 can be used in common with a circuit for writing and reading to the protection information 7, so that the scale of the circuit and the cost can be reduced.

### Second Embodiment

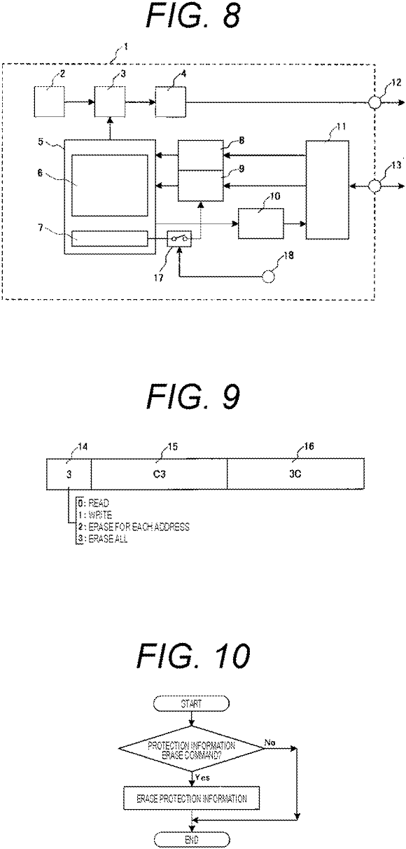

Next, a sensor device according to the second embodiment of the present invention will be described with reference to FIG. 8. FIG. 8 is a configuration diagram of the sensor device according to the second embodiment.

The sensor device of this embodiment is basically the same as the sensor device of the first embodiment, but as shown in FIG. 8, a switch 17 for prohibiting reading from the protection information 7 and an internal terminal 18 for controlling the switch 17 are added.

In this embodiment, the switch 17 and the internal terminal 18 are added, and the protection of the nonvolatile memory 5 can be temporarily canceled by applying a predetermined voltage to the internal terminal 18 to control the switch 17. Thus, the protection information 7 can be erased, and the sensor device 1 can be reused. As a result, even when the protection information 7 is erroneously written in the manufacturing line, the manufacturing yield of the sensor device 1 can be improved by making it possible to reuse it. The internal terminal 18 is arranged inside the sensor device 1 so as not to be accessed from the outside, thereby preventing unauthorized access from the outside. Specifically, the internal terminal 18 is not connected to a connector terminal for communication with an external device, and is arranged in the housing so that the internal terminal 18 cannot be accessed unless the sensor device is disassembled.

### Third Embodiment

Next, a sensor device according to the third embodiment of the present invention will be described with reference to FIG. 9 and FIG. 10. FIG. 9 illustrates a configuration of a communication command for erasing the protection information 7, and FIG. 10 illustrates processing contents for a communication command for erasing the protection information 7.

The sensor device of this embodiment is basically the same as the sensor device of the first embodiment, but processing for a communication command for erasing the protection information 7 as shown in FIG. 9 and processing for a communication command for erasing the protection information 7 as shown in FIG. 10 are added. As shown in FIG. 9, the communication command for erasing the protection information 7 is set to a communication command such as 3C33C in hexadecimal in which specific values are arranged in an operand part 14, an address part 15, and a data part 16. Thus, access from the outside is made difficult and unauthorized access from the outside can be prevented.

Next, processing contents for a communication command for erasing the protection information 7 of the nonvolatile memory 5 in this embodiment will be described with reference to FIG. 10. The communication command sent via the external terminal 13 is processed by the communication unit 11, and when it is determined as a protection information erase command, the erasing unit 9 erases the protection information 7.

In the present embodiment, by adding a communication command for erasing the protection information 7 and a process corresponding thereto, even when the protection information 7 is erroneously written in the manufacturing line of the sensor device 1, the sensor device 1 can be reused by erasing the protection information 7. As a result, even when the protection information 7 is erroneously written in the manufacturing line, the manufacturing yield of the sensor device 1 can be improved by making it possible to reuse it.

### REFERENCE SIGNS LIST

1 sensor device
2 detection unit
3 adjustment unit
4 output unit
5 nonvolatile memory
6 adjustment information
7 protection information
8 writing unit
9 erasing unit
10 reading unit
11 communication unit
12 external terminal
13 external terminal
14 operand part
15 address part
16 data part
17 switch
18 internal terminal

1. A sensor device comprising:
a detection unit configured to detect a physical quantity;
a nonvolatile memory configured to store adjustment information;
an adjustment unit configured to adjust an output signal of the detection unit based on the adjustment information;
an output unit configured to output an output of the adjustment unit to an outside;
a communication unit configured to communicate with the outside;
a writing unit configured to perform writing to the nonvolatile memory based on information from the communication unit;
a reading unit configured to perform reading from the nonvolatile memory based on information from the communication unit; and
an erasing unit configured to perform erasing of the nonvolatile memory based on information from the communication unit,
wherein the nonvolatile memory includes an area to store protection information, and operations of the writing unit and the erasing unit are prohibited based on the protection information.

2. The sensor device according to claim 1, wherein a control terminal is provided inside or outside the sensor device, and the prohibition of operations of the writing unit and the erasing unit is canceled based on the protection information by applying a predetermined voltage to the control terminal.

3. The sensor device according to claim 1, wherein erasing of the protection information is performed by sending a specific command to the communication unit.
